(19) United States
(12) Patent Application Publication
(10) Pub. No.: US 2026/0173247 A1
(43) Pub. Date: Jun. 18, 2026

(54) POWER MODULE FOR VEHICLE AND POWER MODULE CONTROL SYSTEM FOR VEHICLE

(71) Applicants: HYUNDAI MOTOR COMPANY, Seoul (KR); KIA CORPORATION, Seoul (KR); HYUNDAI TRANSYS INC., Seosan-si (KR)

(72) Inventors: Sung Yong Park, Hwaseong-si (KR); Jong Kyong Lim, Hwaseong-si (KR); Byung Hoon Yang, Hwaseong-si (KR); Jun Suk Yoo, Hwaseong-si (KR); Sung Kyu Kim, Hwaseong-si (KR); Tae Yeong Lee, Hwaseong-si (KR); Hyeong Jun Choi, Gwangmyeong-si (KR)

(73) Assignees: HYUNDAI MOTOR COMPANY, Seoul (KR); KIA CORPORATION, Seoul (KR); HYUNDAI TRANSYS INC., Seosan-si (KR)

(21) Appl. No.: 19/207,341

(22) Filed: May 13, 2025

(30) Foreign Application Priority Data
Dec. 13, 2024 (KR) 10-2024-0185634

(51) Int. Cl. H05K 1/02

(52) U.S. Cl. CPC H05K 1/0203; H05K 2201/064; H05K 2201/10151

(57) ABSTRACT

A power module for a vehicle is provided. The power module includes a circuit board, a plurality of power semiconductor switching elements disposed on one surface of the circuit board, and a cooling passage extending along an arrangement of the plurality of power semiconductor switching elements. The cooling passage has a spline shape.

### CROSS-REFERENCE TO RELATED APPLICATION(S)

This application claims benefit of priority to Korean Patent Application No. 10-2024-0185634 filed on Dec. 13, 2024, in the Korean Intellectual Property Office, the disclosure of which is incorporated herein by reference in its entirety.

### TECHNICAL FIELD

The present disclosure relates to a power module for a vehicle and a power module control system for a vehicle.

### BACKGROUND

Eco-friendly vehicles may include a hybrid vehicle (HEV), a plug-in hybrid vehicle (HEV), an electric vehicle (EV), and a fuel cell electric vehicle (FCEV). The power module of the eco-friendly vehicle may receive DC current from a high-voltage battery, may convert the DC current into AC current and may supply the AC current to a motor, and may control torque and rotation speed of the motor by adjusting a magnitude and phase of the AC current.

The power module is a switching element converting DC current received from a high-voltage battery into AC current, and may be damaged when a temperature rises above a certain level due to heat generated during a switching process. Accordingly, the power module may need cooling, and as the cooling performance improves, higher specifications of current may be converted.

### SUMMARY

A power module for a vehicle according to an embodiment of the present disclosure may (e.g., effectively) increase overall cooling performance (e.g., cooling efficiency and a refrigerant circulation rate) for a plurality of power semiconductor switching elements.

A power module control system for a vehicle according to an embodiment of the present disclosure may (e.g., accurately) estimate a junction temperature even if a temperature sensor is not disposed close to a power semiconductor switching element.

A power module for a vehicle according to an embodiment of the present disclosure may include a circuit board, a plurality of power semiconductor switching elements disposed on one surface (e.g., a first surface) of the circuit board, and a cooling passage extending along an arrangement of the plurality of power semiconductor switching elements. The cooling passage may have a spline shape.

For example, the plurality of power semiconductor switching elements may include at least six power semiconductor switching elements arranged in a row.

For example, the circuit board may include a DC electrode, an AC electrode, and a controller connection portion. The plurality of power semiconductor switching elements may receive DC power from the DC electrode, may convert the DC power into AC power based on a control signal input from the controller connection portion and may output the AC power to the AC electrode. The at least six power semiconductor switching elements may form a single inverter converting the DC power into AC power.

For example, the power module for a vehicle may further include a DC link capacitor disposed on the circuit board to be electrically connected between the plurality of power semiconductor switching elements and the DC electrode.

For example, a widthwise cross-section of the cooling passage may have a concave-convex shape, and the concave-convex shape may be continuously extended in a longitudinal direction of the cooling passage.

For example, an average width of the cooling passage may be uniform in the longitudinal direction of the cooling passage, and the concave-convex shape may be uniform in the longitudinal direction of the cooling passage.

For example, the concave-convex shape may be more biased toward a portion closer to the circuit board among (e.g., of) a plurality of portions of the cooling passage.

For example, the portion closer to the circuit board, among the plurality of portions of the cooling passage, may have a concave-convex shape in a circumferential direction of the cooling passage, and a portion farther from the circuit board, among the plurality of portions of the cooling passage, may have a uniform radius in the circumferential direction of the cooling passage.

For example, the cooling passage may be disposed on the other surface (e.g., second surface) of the circuit board. The cooling passage may overlap a portion of the circuit board and the plurality of power semiconductor switching elements in a direction in which one surface and the other surface of the circuit board face each other, and the cooling passage may not overlap the remainder of the circuit board.

For example, the circuit board may include an insulating layer, a first metal layer disposed on one surface of the insulating layer, and a second metal layer disposed on the other surface of the insulating layer. The plurality of power semiconductor switching elements may overlap a portion of the first metal layer, a portion of the insulating layer, and a portion of the second metal layer, in a direction in which the plurality of power semiconductor switching elements and the cooling passage face each other.

For example, the power module for a vehicle may further include a temperature sensor disposed on the circuit board so as to overlap the cooling passage in a direction in which one surface and the other surface of the circuit board face each other and not to overlap the plurality of power semiconductor switching elements.

For example, a power module control system for a vehicle may include a power module for a vehicle, including a circuit board, a plurality of power semiconductor switching elements disposed on one surface of the circuit board, and a cooling passage extending along an arrangement of the plurality of power semiconductor switching elements. The power module control system includes a temperature sensor sensing a temperature of the cooling passage or the circuit board, and a controller controlling switching of the plurality of power semiconductor switching elements so that the plurality of power semiconductor switching elements convert DC power into AC power. The controller may generate a junction temperature value by adding a temperature difference value based on at least one of a current or voltage of the plurality of power semiconductor switching elements, to a temperature value sensed by the temperature sensor.

For example, the controller may selectively control limiting or stopping an output of the plurality of power semiconductor switching elements, according to the junction temperature value.

For example, the controller may select one of a first state, a second state and a third state based on the junction temperature value, and may inactivate a limitation of the output of the plurality of power semiconductor switching elements in a case of the first state, may activate the limitation of the output of the plurality of power semiconductor switching elements in a case of the second state, and may stop the output of the plurality of power semiconductor switching elements in a case of the third state.

For example, the controller may apply a temperature difference value corresponding to a current and voltage of the plurality of power semiconductor switching elements from a preset estimation data to the temperature value sensed by the temperature sensor to generate the junction temperature value.

For example, the power module for a vehicle may further include a current sensor disposed on the circuit board to sense a current of the plurality of power semiconductor switching elements, and the controller may apply the temperature difference value based on a current value sensed by the current sensor to a temperature value sensed by the temperature sensor to generate the junction temperature value.

For example, the plurality of power semiconductor switching elements may include at least six power semiconductor switching elements arranged in a row, and the temperature sensor may be disposed on the circuit board so as to overlap the cooling passage in a direction in which one surface and the other surface of the circuit board face each other and not to overlap the plurality of power semiconductor switching elements.

For example, the controller may generate a plurality of junction temperature values respectively corresponding to the plurality of power semiconductor switching elements.

For example, the cooling passage may have a spline shape.

### BRIEF DESCRIPTION OF DRAWINGS

The above and other aspects and features of the present disclosure may understood from the following detailed description, taken in conjunction with the accompanying drawings.

FIG. 1 is a circuit diagram illustrating a power module for a vehicle and a power module control system for a vehicle according to an embodiment of the present disclosure.

FIG. 2 is a plan view illustrating a power module for a vehicle and a power module control system for a vehicle according to an embodiment of the present disclosure.

FIG. 3 is a cross-sectional view illustrating a spline-shaped cooling passage of a power module for a vehicle and a power module control system for a vehicle according to an embodiment of the present disclosure and an upper structure of the cooling passage.

FIG. 4 is a cross-sectional view illustrating a partial spline-shaped cooling passage of a power module for a vehicle and a power module control system for a vehicle according to an embodiment of the present disclosure and an upper structure of the cooling passage.

FIG. 5 is a side view illustrating an interior of a cooling passage of a power module for a vehicle and a power module control system for a vehicle according to an embodiment of the present disclosure and an upper structure of the cooling passage.

FIG. 6 is a flowchart illustrating an operation of a controller of a power module control system for a vehicle according to an embodiment of the present disclosure.

FIG. 7 is a graph illustrating preset estimation data of a controller of a power module control system for a vehicle according to an embodiment of the present disclosure.

### DETAILED DESCRIPTION

Hereinafter, the present disclosure may make various changes and have various embodiments, specific embodiments thereof are described and illustrated in the drawings. However, the embodiments are not intended for limiting the disclosure. The idea of the present disclosure should be construed to extend to any alterations, equivalents, and substitutes besides the accompanying drawings.

Although the terms first, second, and the like may be used herein to describe various elements, these elements should not be limited by these terms. These terms are generally used to distinguish one element from another. For example, a first element could be termed a second element, and, similarly, a second element could be termed a first element, without departing from the scope of the present disclosure. The term of and/or encompasses a combination of plural items or any one of the plural items.

The term used herein is for the purpose of describing particular embodiments and is not intended to be limiting of the present disclosure. The singular also includes the plural unless specifically stated otherwise in the phrase. It may be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise provided, terms including technical and scientific terms used herein have the meaning as that which would be commonly understood by one of ordinary skill in the art to which example embodiments of the present disclosure belong. It may be further understood that the terms, such as those provided in commonly used dictionaries, should be interpreted as having meanings that are consistent with their meanings in the context of the relevant art and may not be interpreted in an idealized or overly formal sense unless expressly so provided herein.

In the present disclosure, the vehicle (e.g., electric vehicle) refers to various vehicles for moving transported objects such as people or animals, things, and the like, from a departure point to a destination. Such vehicles are not limited to vehicles driving on roads or tracks.

Hereinafter, embodiments of the present disclosure are described with reference to the attached drawings.

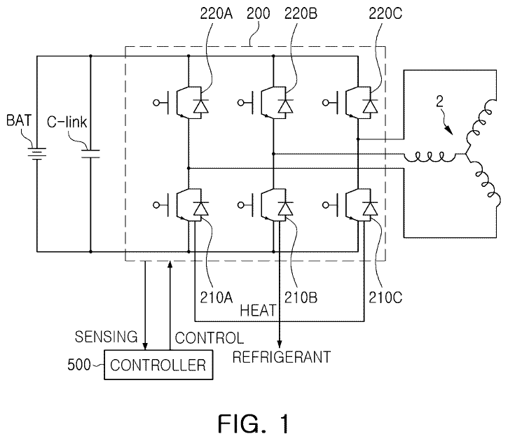

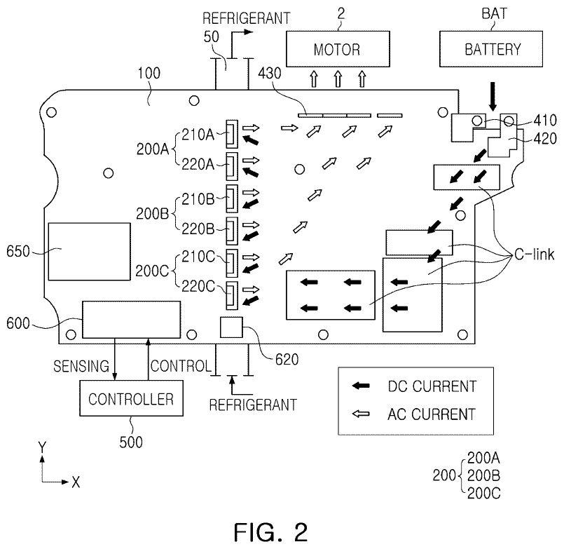

Referring to FIGS. 1 and 2, a power module for a vehicle according to an embodiment of the present disclosure may include a circuit board 100, a plurality of power semiconductor switching elements 210A, 210B, 210C, 220A, 220B and 220C, and a cooling passage 50. A power module control system for a vehicle according to an embodiment of the present disclosure may include the power module for a vehicle, and may further include a temperature sensor 620 and a controller 500.

The plurality of power semiconductor switching elements 210A, 210B, 210C, 220A, 220B and 220C may be disposed on one surface (e.g., a +Z-direction surface) of the circuit board 100, and the plurality of power semiconductor switching elements may be at least six power semiconductor switching elements arranged in a row. For example, each of the plurality of power semiconductor switching elements 210A, 210B, 210C, 220A, 220B and 220C may include a structure in which a transistor and a diode are coupled to each other, and the transistor may be implemented as an insulated gate bipolar transistor (IGBT) or a metal oxide semiconductor field effect transistor (MOSFET), but the present disclosure is not limited thereto. Switching may refer to switching between an on state and an off state of the transistor.

For example, the at least six power semiconductor switching elements 210A, 210B, 210C, 220A, 220B and 220C may form a single inverter 200 converting a DC power (DC CURRENT of FIG. 2) into an AC power (AC CURRENT of FIG. 2). The single inverter 200 may include at least one of an A-phase power semiconductor switching element 200A, a B-phase power semiconductor switching element 200B, and a C-phase power semiconductor switching element 200C. The A-phase power semiconductor switching element 200A may include power semiconductor switching elements 210A and 220A, the B-phase power semiconductor switching element 200B may include power semiconductor switching elements 210B and 220B, and the C-phase power semiconductor switching element 200C may include power semiconductor switching elements 210C and 220C.

Each of the plurality of power semiconductor switching elements 210A, 210B, 210C, 220A, 220B and 220C may be inserted into each of the plurality of recess portions (or through-holes) of the circuit board 100, but the present disclosure is not limited thereto. Depending on the design, each of the plurality of power semiconductor switching elements 210A, 210B, 210C, 220A, 220B and 220C may be soldered to the circuit board 100, may be connected to the circuit board 100 via a bonding wire, or may be bonded to the circuit board 100 via an adhesive material or fastened to the circuit board 100. For example, each of the plurality of power semiconductor switching elements 210A, 210B, 210C, 220A, 220B and 220C may have three or four terminals (e.g., a gate terminal, a collector terminal, and an emitter terminal), and each of the terminals may be connected to electrical paths (e.g., a plurality of patterns of the first metal layer) of the circuit board 100.

The at least six power semiconductor switching elements 210A, 210B, 210C, 220A, 220B and 220C may be formed of at least six separate components, and the at least six separate components may be provided as a discrete power module. The discrete power module may have a structure in which the number of power semiconductor switching elements 210A, 210B, 210C, 220A, 220B and 220C may be flexibly adjusted (e.g., the number of arrangements, and the number of uses) according to the current specifications (or the inverter requirements), and may have a structure in which the power semiconductor switching elements 210A, 210B, 210C, 220A, 220B and 220C may be (e.g., efficiently) replaced in response to damage to some of the power semiconductor switching elements. For example, the discrete power module may be efficient (e.g., cost reduction) in a motor control system (e.g., a torque vectoring system) having high rated voltage (e.g., 800 V) and low rated current (e.g., 40 Arms), but the present disclosure is not limited thereto.

The cooling passage 50 may extend along an arrangement of the plurality of power semiconductor switching elements 210A, 210B, 210C, 220A, 220B and 220C. As compared to a structure in which the plurality of power semiconductor switching elements are integrated into a single component, a structure in which the plurality of power semiconductor switching elements 210A, 210B, 210C, 220A, 220B and 220C are arranged in a row may bring the cooling passage 50 closer to the plurality of power semiconductor switching elements 210A, 210B, 210C, 220A, 220B and 220C overall, and may thus be an (e.g., efficient) structure for cooling the plurality of power semiconductor switching elements 210A, 210B, 210C, 220A, 220B and 220C.

For example, the cooling passage 50 may be disposed on the other surface (e.g., −Z-direction surface) of the circuit board 100, and may overlap a portion (e.g., a central portion) of the circuit board 100, and the plurality of power semiconductor switching elements 210A, 210B, 210C, 220A, 220B and 220C, in a direction (e.g., Z-direction) in which one surface and the other surface of the circuit board 100 face each other, and may not overlap the remainder (e.g., X-direction surface) of the circuit board 100. Accordingly, a (e.g., required) length of the cooling passage 50 for cooling the plurality of power semiconductor switching elements 210A, 210B, 210C, 220A, 220B and 220C may be short.

The shorter the (e.g., required) length of the cooling passage 50, the higher the heat concentration in an object (e.g., a plurality of power semiconductor switching elements) cooled by the cooling passage 50. As the heat concentration increases, the heat circulation speed of the refrigerant (e.g., cooling water, cooling gas) passing through the cooling passage 50 may become more useful (e.g., important) during long-term use. The heat circulation speed may become faster as a flow speed of the refrigerant in the cooling passage 50 becomes faster.

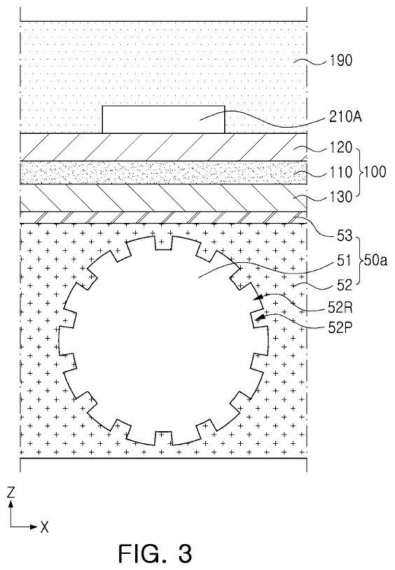

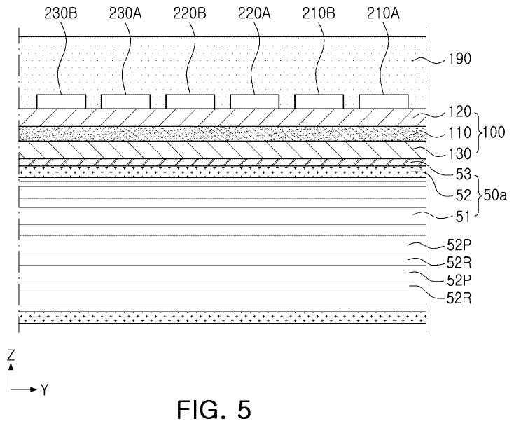

Referring to FIGS. 2, 3 and 5, the cooling passages 50 and 50a may have spline shapes 52P and 52R. A widthwise cross-section (e.g., an X-Z cross-section) of the cooling passages 50 and 50a may have a concave-convex shape, and the concave-convex shape may be (e.g., continuously) extended in a longitudinal direction (e.g., Y-direction) of the cooling passages 50 and 50a. For example, an average width (e.g., a diameter) of the cooling passages 50 and 50a may be uniform in the longitudinal direction (e.g., Y-direction) of the cooling passages 50 and 50a, and the concave-convex shape may be uniform in the longitudinal direction (e.g., Y-direction) of the cooling passages 50 and 50a.

The spline shapes 52P and 52R may (e.g., efficiently) increase a surface area in which the refrigerant collides within the cooling passages 50 and 50a, thereby increasing the cooling efficiency (or lowering the thermal resistance). Additionally, the spline shapes 52P and 52R may reduce the refrigerant colliding in the flow direction (e.g., Y-direction), and thus may increase the flow speed (corresponding to the heat circulation speed) of the refrigerant. That is, the spline shapes 52P and 52R may (e.g., effectively) increase overall cooling performance (e.g., cooling efficiency and a refrigerant circulation rate) for the plurality of power semiconductor switching elements 210A, 210B, 210C, 220A, 220B and 220C, and may be efficient for cooling a discrete power module.

The cooling passages 50 and 50a may include a cooling member 52 and a through-portion 51 penetrating through the cooling member 52. The cooling member 52 may be a heat medium between the plurality of power semiconductor switching elements 210A, 210B, 210C, 220A, 220B and 220C and the refrigerant, and the spline shapes 52P and 52R may be formed on a surface of the cooling member 52. The refrigerant may receive heat through the cooling member 52 by passing through the through-portion 51. A temperature of the refrigerant discharged from the through-portion 51 may be lowered outside the power module for a vehicle, and the refrigerant having the lowered temperature may be introduced into the through-portion 51.

The circuit board 100 may include an insulating layer 110, a first metal layer 120 disposed on one surface (e.g., a +Z-direction surface) of the insulating layer 110, and a second metal layer 130 disposed on the other surface (e.g., a −Z-direction surface) of the insulating layer 110. For example, the circuit board 100 may be implemented as an Active Metal Brazed (AMB) substrate or a Direct Bonded Copper (DBC) substrate, and the insulating layer 110 may be implemented as a ceramic layer, and each of the first and second metal layers 120 and 130 may be implemented as a copper layer, but the present disclosure is not limited thereto.

Some regions of the insulating layer 110 may overlap the first metal layer 120 in an up-down (e.g., vertical) direction (Z-direction), and the remaining regions of the insulating layer 110 may not overlap the first metal layer 120 in the vertical direction (Z-direction). For example, the first metal layer before patterning may be formed to overlap an (e.g., entire) region of the insulating layer 110, and a portion of the first metal layer before patterning may be removed by a patterning method (e.g., a photolithography method), and the first metal layer 120 after patterning may include a plurality of patterns (corresponding to a plurality of electrical paths) separated from each other.

The plurality of power semiconductor switching elements 210A, 210B, 210C, 220A, 220B and 220C may overlap a portion (e.g., a central portion) of the first metal layer 120, a portion (e.g., a central portion) of the insulating layer 110, and a portion (e.g., a central portion) of the second metal layer 130, in a direction (e.g., a Z-direction) in which the plurality of power semiconductor switching elements and the cooling passages 50 and 50a face each other. Accordingly, heat generated in the first metal layer 120 of the circuit board 100 according to the flow of DC power (DC CURRENT in FIG. 2) and AC power (AC CURRENT in FIG. 2) may also be cooled by the cooling passages 50 and 50a.

The second metal layer 130 may dissipate the heat generated from the plurality of power semiconductor switching elements 210A, 210B, 210C, 220A, 220B and 220C to the cooling passages 50 and 50a, and may be electrically separated from the first metal layer 120 by the insulating layer 110. For example, the second metal layer 130 may be attached to the cooling member 52 through a heat transfer layer 53 having a high thermal conductivity coefficient. For example, the heat transfer layer 53 may be a thermal interface material (TIM), and may be implemented as an adhesive member (e.g., an adhesive polymer) having a high thermal conductivity coefficient.

An encapsulating material 190 may be included in the power module for a vehicle may be disposed on the circuit board 100 and may encapsulate the plurality of power semiconductor switching elements 210A, 210B, 210C, 220A, 220B and 220C. For example, the encapsulating material 190 may include a molding material such as Epoxy Molding Compound (EMC) or a silicone gel, but the present disclosure is not limited thereto.

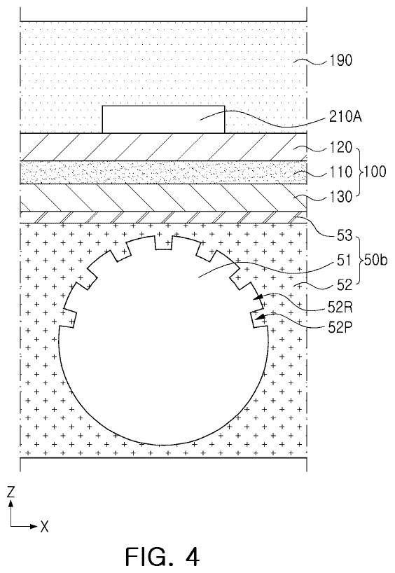

Referring to FIGS. 2 and 4, a concave-convex shape of the spline shapes 52P and 52R may be more biased toward a portion (e.g., +Z-direction portion) closer to the circuit board 100, among the plurality of portions of the cooling passages 50 and 50b, and the spline shapes 52P and 52R may have the concave-convex shape in a circumferential direction of the cooling passages 50 and 50b (e.g., in a direction of wrapping a Y-direction axis). Accordingly, the cooling passages 50 and 50b may increase a flow rate of a refrigerant (corresponding to a heat circulation rate) while (e.g., barely) reducing the cooling efficiency (or while barely increasing thermal resistance). For example, a portion (e.g., a −Z-direction portion) further from the circuit board 100, among the plurality of portions of the cooling passages 50 and 50b, may have a uniform radius in the circumferential direction (e.g., a direction of wrapping the Y-direction axis) of the cooling passages 50 and 50b.

Referring to FIG. 2, a power module for a vehicle according to an embodiment of the present disclosure may include DC electrodes 410 and 420, an AC electrode 430, and a controller connection portion 600. Each of the DC electrodes 410 and 420, the AC electrode 430, and the controller connection portion 600 may be disposed adjacently to an edge of the circuit board 100. For example, the DC electrodes 410 and 420 and the AC electrodes 430 may be biased to one side (e.g., in a +X-direction and/or in a +Y-direction) from the plurality of power semiconductor switching elements 210A, 210B, 210C, 220A, 220B and 220C and may be disposed on the circuit board 100, and the controller connection unit 600 may be biased to the other side (e.g., in a −X-direction and/or in a −Y-direction) from the plurality of power semiconductor switching elements 210A, 210B, 210C, 220A, 220B and 220C and may be disposed on the circuit board 100.

The DC electrodes 410 and 420 may be electrically connected to a battery (BAT in FIG. 1), may receive DC power (DC CURRENT) from the battery (BAT in FIG. 1), and may transmit the DC power (DC CURRENT) to the plurality of power semiconductor switching elements 210A, 210B, 210C, 220A, 220B and 220C through the circuit board 100. The AC electrode 430 may receive AC power (AC CURRENT) from the plurality of power semiconductor switching elements 210A, 210B, 210C, 220A, 220B and 220C through the circuit board 100, and the AC electrode 430 may output the AC power (AC CURRENT) to the motor 2 (see FIG. 1).

The controller connection portion 600 may be electrically connected to the controller 500, may receive a control signal from the controller 500, and may transmit the control signal to the plurality of power semiconductor switching elements 210A, 210B, 210C, 220A, 220B and 220C through the circuit board 100.

Referring to FIGS. 1 and 2, a power module for a vehicle according to an embodiment of the present disclosure may further include a DC link capacitor (C-link) disposed on the circuit board 100 so as to be electrically connected between the plurality of power semiconductor switching elements 210A, 210B, 210C, 220A, 220B and 220C and the DC electrodes 410 and 420.

Referring to FIG. 2, the power module for a vehicle and the power module control system for a vehicle according to an embodiment of the present disclosure may further include a temperature sensor 620 disposed on a circuit board 100 so as to overlap the cooling passage 50 in a direction (e.g., in the Z-direction) in which one surface and the other surface of the circuit board 100 face each other and not to overlap the plurality of power semiconductor switching elements 210A, 210B, 210C, 220A, 220B and 220C. For example, the temperature sensor 620 may be implemented as a negative temperature coefficient of resistance (NTC) sensor.

The temperature sensor 620 may sense a temperature of the cooling passage 50 or the circuit board 100, and may not be in direct contact with the plurality of power semiconductor switching elements 210A, 210B, 210C, 220A, 220B and 220C. Accordingly, a temperature value sensed by the temperature sensor 620 may be different from a junction temperature between the plurality of power semiconductor switching elements 210A, 210B, 210C, 220A, 220B and 220C and the circuit board 100.

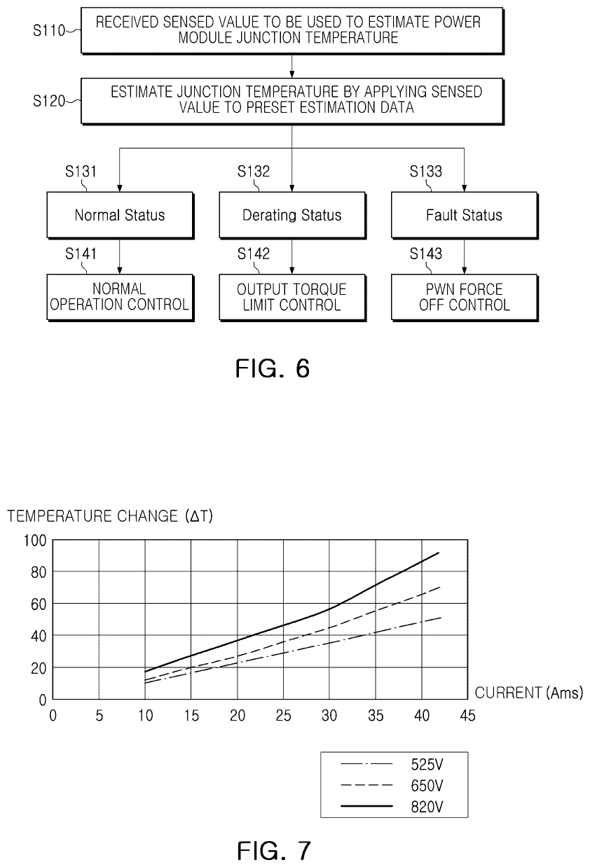

Referring to FIGS. 2 and 6, the power module control system for a vehicle according to an embodiment of the present disclosure may include a controller 500 configured to control switching of the plurality of power semiconductor switching elements 210A, 210B, 210C, 220A, 220B and 220C so that the plurality of power semiconductor switching elements 210A, 210B, 210C, 220A, 220B and 220C may convert the DC power (DC CURRENT) into the AC power (AC CURRENT). The controller 500 may generate a junction temperature value (S120) obtained by adding a temperature difference value based on at least one of a current and voltage of the plurality of power semiconductor switching elements 210A, 210B, 210C, 220A, 220B and 220C, to a temperature value sensed (S110) by the temperature sensor 620.

Accordingly, the power module control system for a vehicle may estimate a junction temperature between the plurality of power semiconductor switching elements 210A, 210B, 210C, 220A, 220B and 220C and the circuit board 100, even if the temperature sensor 620 is not disposed close to the plurality of power semiconductor switching elements 210A, 210B, 210C, 220A, 220B and 220C.

Additionally, according to a structure in which the plurality of power semiconductor switching elements 210A, 210B, 210C, 220A, 220B and 220C and the cooling passage 50 are arranged in parallel, a temperature difference value (ΔT in Equation 1) between the temperature value sensed by the temperature sensor 620 and the junction temperature may be barely affected by external factors (e.g., an environment surrounding the power module for a vehicle, and a detailed structure inside the vehicle, and the like). Accordingly, the power module control system for a vehicle may accurately estimate the junction temperature. When the cooling passage 50 has a spline shape, the junction temperature may be estimated more accurately.

For example, the controller 500 may use the following mathematical expression (e.g., equation) 1. Here, T_{junction} is a junction temperature value, Tₛₑₙₛₒᵣ is a temperature value sensed by the temperature sensor 620, and ΔT is a temperature difference value.

T_{junction}=Tₛₑₙₛₒᵣ+ΔT [Equation 1]

The controller 500 may selectively (S131, S132 and S133) control (S141, S142 and S143) limiting or stopping an output of the plurality of power semiconductor switching elements 210A, 210B, 210C, 220A, 220B and 220C according to a junction temperature value (T_{junction} of Equation 1). Accordingly, the power module control system for a vehicle may also prevent damage due to overheating of the plurality of power semiconductor switching elements 210A, 210B, 210C, 220A, 220B and 220C while further increasing an overall output (or efficiency) of the plurality of power semiconductor switching elements 210A, 210B, 210C, 220A, 220B and 220C.

For example, the controller 500 may select one of a first state, a second state and a third state based on the junction temperature value. In the case of the first state (e.g., Normal Status) (S131), the controller 500 may inactivate the limitation of the output of the plurality of power semiconductor switching elements 210A, 210B, 210C, 220A, 220B and 220C (S141). In the case of the second state (e.g., Derating Status) (S132), the controller 500 may activate the limitation of the output of the plurality of power semiconductor switching elements 210A, 210B, 210C, 220A, 220B and 220C (S142). In the case of the third state (e.g., Fault Status) (S133), the controller 500 may stop the output of the plurality of power semiconductor switching elements 210A, 210B, 210C, 220A, 220B and 220C (S143).

For example, the controller 500 may generate a control signal based on pulse width modulation. In the case of the second state (e.g., Derating Status), the controller 500 may limit a pulse width of the control signal to a specific value. In the case of first state (e.g., Normal Status), the controller 500 may release a limitation of the pulse width of the control signal. In the case of the third state (e.g., Fault Status), the controller 500 may set the pulse width of the control signal to 0%.

Referring to FIGS. 2, 6 and 7, the controller 500 may generate (S120) a junction temperature value (T_{junction} in Equation 1) by applying a temperature difference value (ΔT) corresponding to the current and voltage of the plurality of power semiconductor switching elements 210A, 210B, 210C, 220A, 220B and 220C in a preset estimation data (e.g., a plurality of curves in FIG. 7) to a temperature value (Tₛₑₙₛₒᵣ in Equation 1) sensed by the temperature sensor 620.

For example, the preset estimation data (e.g., the plurality of curves in FIG. 7) may be determined according to an experiment before designing the controller 500 (or before data update). For example, the controller 500 may be provided with data on a correspondence between a current and the temperature difference value (ΔT) for each of different rated voltages (e.g., 525 V, 650 V and 820 V) of a battery (BAT in FIG. 1) in advance, and may generate the temperature difference value (ΔT) by applying real-time current to the correspondence data of the set rated voltage.

For example, the controller 500 may determine the current based on the current command (or a target torque of the motor) corresponding to the control signal. Alternatively, the power module for a vehicle may further include a current sensor (650 of FIG. 2) disposed on the circuit board 100 to sense (S110) currents of the plurality of power semiconductor switching elements 210A, 210B, 210C, 220A, 220B and 220C, and the controller 500 may apply a temperature difference value based on the current value sensed (S110) by the current sensor (650) to the temperature value sensed by the temperature sensor 620, thus generating a junction temperature value (S120). For example, the current sensor (650 of FIG. 2) may be implemented to sense a current and/or voltage of a resistor connected to a shunt in the first metal layer 120 or may be implemented as a hall sensor, but the present disclosure is not limited thereto.

For example, the junction temperature value (T_{junction} in Equation 1) may be a junction temperature value of one selected from the plurality of power semiconductor switching elements 210A, 210B, 210C, 220A, 220B and 220C (e.g., a power semiconductor switching element closest to a point at which the cooling performance of the cooling passage is the lowest). Depending on the design, the controller 500 may generate (S120) a plurality of junction temperature values corresponding to each of the plurality of power semiconductor switching elements 210A, 210B, 210C, 220A, 220B and 220C. Here, the preset estimation data (e.g., a plurality of curves of FIG. 7) may also be provided for each of the plurality of power semiconductor switching elements 210A, 210B, 210C, 220A, 220B and 220C.

The controller 500 may be implemented as an electronic control unit (ECU) of a vehicle or a computer system (e.g., a microcontroller or an embedded system). The computer system may include at least one processor, a computer-readable storage medium, a communication bus, an input/output device, an input/output interface, and a network communication interface, and may execute one or more programs for generating the junction temperature value. For example, the computer-readable storage medium may store the one or more programs, and may store the preset estimation data (e.g., the plurality of curves of FIG. 7).

A power module for a vehicle according to an embodiment of the present disclosure may (e.g., effectively) increase overall cooling performance (e.g., cooling efficiency and a refrigerant circulation rate) for a plurality of power semiconductor switching elements.

A power module control system for a vehicle according to an embodiment of the present disclosure may (e.g., accurately) estimate a junction temperature even if a temperature sensor is not disposed close to power semiconductor switching elements.

Although the disclosure has been described with reference to the above embodiments, it may be understood by those skilled in the art that the disclosure may be variously modified and changed within the scope and spirit of the disclosure described in the following patent claims.

What is claimed is:

1. A power module for a vehicle, comprising:
a circuit board;
a plurality of power semiconductor switching elements disposed on a surface of the circuit board; and
a cooling passage extending along an arrangement of the plurality of power semiconductor switching elements,
wherein the cooling passage has a spline shape.

2. The power module for a vehicle according to claim 1, wherein the plurality of power semiconductor switching elements include at least six power semiconductor switching elements arranged in a row.

3. The power module for a vehicle according to claim 2, wherein the circuit board includes a DC electrode, an AC electrode, and a controller connection portion,
the plurality of power semiconductor switching elements receives DC power from the DC electrode, converts the DC power into AC power based on a control signal input from the controller connection portion, and outputs the AC power to the AC electrode, and
the at least six power semiconductor switching elements form a single inverter converting the DC power into AC power.

4. The power module for a vehicle according to claim 3, further comprising
a DC link capacitor disposed on the circuit board to be electrically connected between the plurality of power semiconductor switching elements and the DC electrode.

5. The power module for a vehicle according to claim 1, wherein a widthwise cross-section of the cooling passage has a concave-convex shape, and
the concave-convex shape is extended in a longitudinal direction of the cooling passage.

6. The power module for a vehicle according to claim 5, wherein an average width of the cooling passage is uniform in the longitudinal direction of the cooling passage, and
the concave-convex shape is uniform in the longitudinal direction of the cooling passage.

7. The power module for a vehicle according to claim 5, wherein the concave-convex shape is biased toward a portion closer to the circuit board of a plurality of portions of the cooling passage.

8. The power module for a vehicle according to claim 7, wherein the portion closer to the circuit board of the plurality of portions of the cooling passage has a concave-convex shape in a circumferential direction of the cooling passage, and
a portion farther from the circuit board of the plurality of portions of the cooling passage has a uniform radius in the circumferential direction of the cooling passage.

9. The power module for a vehicle according to claim 1, wherein the surface is a first surface, and wherein the cooling passage is disposed a second surface of the circuit board, and overlaps a portion of the circuit board and the plurality of power semiconductor switching elements in a direction in which the first surface and the second surface of the circuit board face each other, and does not overlap a remainder of the circuit board.

10. The power module for a vehicle according to claim 9, wherein the circuit board includes an insulating layer, a first metal layer disposed on a surface of the insulating layer, and a second metal layer disposed on another surface of the insulating layer, and
the plurality of power semiconductor switching elements overlap a portion of the first metal layer, a portion of the insulating layer, and a portion of the second metal layer, in a direction in which the plurality of power semiconductor switching elements and the cooling passage face each other.

11. The power module for a vehicle according to claim 9, further comprising
a temperature sensor disposed on the circuit board to overlap the cooling passage in a direction in which the first surface and the second surface of the circuit board face each other and does not overlap the plurality of power semiconductor switching elements.

12. A power module control system for a vehicle, comprising
a power module for a vehicle, including a circuit board, a plurality of power semiconductor switching elements disposed on a surface of the circuit board, and a cooling passage extending along an arrangement of the plurality of power semiconductor switching elements;
a temperature sensor sensing a temperature of the cooling passage or the circuit board; and
a controller controlling switching of the plurality of power semiconductor switching elements, the plurality of power semiconductor switching elements convert DC power into AC power,
wherein the controller generates a junction temperature value obtained by adding a temperature difference value based on at least one of a current or voltage of the plurality of power semiconductor switching elements to a temperature value sensed by the temperature sensor.

13. The power module control system for a vehicle according to claim 12, wherein the controller selectively limits or stops an output of the plurality of power semiconductor switching elements according to the junction temperature value.

14. The power module control system for a vehicle according to claim 13, wherein the controller selects one of a first state, a second state, and a third state based on the junction temperature value, and inactivates a limitation of the output of the plurality of power semiconductor switching elements in the first state, activates the limitation of the output of the plurality of power semiconductor switching elements in the second state, and stops the output of the plurality of power semiconductor switching elements in the third state.

15. The power module control system for a vehicle according to claim 12, wherein the controller applies a temperature difference value corresponding to a current and voltage of the plurality of power semiconductor switching elements from a preset estimation data to the temperature value sensed by the temperature sensor to generate the junction temperature value.

16. The power module control system for a vehicle according to claim 12, wherein the power module for a vehicle further includes a current sensor disposed on the circuit board to sense a current of the plurality of power semiconductor switching elements, and
wherein the controller applies the temperature difference value based on a current value sensed by the current sensor to a temperature value sensed by the temperature sensor to generate the junction temperature value.

17. The power module control system for a vehicle according to claim 12, wherein the plurality of power semiconductor switching elements include at least six power semiconductor switching elements arranged in a row.

18. The power module control system for a vehicle according to claim 17, wherein the surface is a first surface, and wherein the temperature sensor is disposed on the circuit board to overlap the cooling passage in a direction in which the first surface and a second surface of the circuit board face each other and not to overlap the plurality of power semiconductor switching elements.

19. The power module control system for a vehicle according to claim 12, wherein the controller generates a plurality of junction temperature values corresponding to the plurality of power semiconductor switching elements.

20. The power module control system for a vehicle according to claim 12, wherein the cooling passage has a spline shape.
